(19) United States
(12) Patent Application Publication
(10) Pub. No.: US 2008/0192442 A1
(43) Pub. Date: Aug. 14, 2008

(54) Dual Hinge Bracket

(76) Inventors: Michael B. Lupton, Highlands Ranch, CO (US); Paul V. Campbell, Lakewood, CO (US); Denny M. Rogers, Aurora, CO (US)

Correspondence Address: BERENBAUM, WEINSHIENK & EASON, P.C, 370 17TH STREET, SUITE 4800, DENVER, CO, 80202, US

(21) Appl. No.: 11/674,586

(22) Filed: Feb. 13, 2007

(51) Int. Cl. H05K 7/16; H05K 5/00

(52) U.S. Cl. 361/725

(57) ABSTRACT

A dually hinged apparatus for mounting an equipment component in a moveable disposition within a housing, wherein the apparatus is adapted for mounting the equipment component within the housing in a movable disposition. A system and a method of mounting the equipment component within the housing using the dually hinged apparatus are also disclosed.

### BACKGROUND

The developments hereof relate to hinged brackets in general, and particularly as these may be used in applications for mounting communications or data equipment within a telecommunications system or enclosure. These developments further provide enhanced accessibility to both mounted and un-mounted communications or data equipment within the telecommunications system or enclosure.

As a background on methods of rear accessibility in communication rack assemblies, generally, it may first be noted that components within wall mounted enclosures that require rear accessibility would normally require that the entire enclosure system swing out from the wall, or that the mounting unit swing from the enclosure system itself, to allow rear accessibility to the components mounted within the enclosure.

Typically, larger units for telecommunications equipment are not wall-mounted, they are either enclosed in a cabinet and rest or anchored to the floor or rack mounted and anchored to the floor. Larger assemblies are anchored to a set of upright rails, affixed to a base on a floor or other foundation, and connected by a rail at the top, forming a substantially rectangular shape. These larger assemblies may typically allow access from both the front and the back, and do not give rise to the accessibility issues raised by typically wall-mounted smaller units for telecommunications equipment.

Smaller units for telecommunications equipment mounting are generally contained within an enclosure, such as a large, substantially square enclosure. Such an enclosure may be mounted to a wall on one side, and the opposite side may be the door that provides access to the telecommunications equipment within the enclosure. Such enclosures may be designed to be mounted outdoors and made of materials that may withstand extreme temperatures and protect the telecommunications equipment within. The fact that these enclosures are often wall-mounted and required to give protection from the elements gives rise to a need for a lighter, more compact design. However, in maximizing the use of space within the enclosure to create a more compact arrangement of telecommunications equipment within the enclosure, the issue of access to every component may arise.

Considerations that are generally encountered in designing systems for smaller telecommunications enclosures encompass space, accessibility, enclosure size, maintainability, inspectability, reliability, and serviceability.

Prior solutions to address access to equipment that requires rear accessibility and that are mounted within an enclosure give rise to space, cost, and compromised accessibility issues. One solution may require the entire enclosure to have a hinged base on the side that is mounted to the wall, wherein that the entire base compartment swings out from the wall. This solution in itself requires a larger total volume enclosure that is capable of protruding from the wall a greater distance. This also leads to an increase in cost, and requires a greater amount of space within the enclosure so that the telecommunications equipment may be disposed efficiently within the system. Another prior solution may require mounting the electronic equipment in an enclosure that is designed so that the rails to which the equipment is mounted within the enclosure would swing independently of the enclosure. This also requires a larger enclosure and is also more costly.

The solution presented herein allows for individual components that require rear access for communication or power terminations to swing themselves, instead of requiring the entire enclosure swing outward, or the rails themselves swing outward. This solution may thereby save on space, material and overall costs. Considerations that are encountered encompass space, accessibility, enclosure size, maintainability, inspectability, reliability, and serviceability.

### SUMMARY

The present apparatus is directed generally to a dual hinge bracket that allows communications and or data equipment components to swing outward from mounting points within a standard size communication rack assembly to provide rear access to the components for communications and power wiring. The apparatus may have counter swinging hinges that allow the component to move horizontally within mounting rails and swing outward and away from the rails themselves.

### BRIEF DESCRIPTION OF THE DRAWINGS

Apparatuses and methods hereof will be better understood by reference to the following more detailed description and accompanying drawings in which:

FIG. 1 is an isometric view of an apparatus according to the present disclosure;

FIG. 2 is a side view of the apparatus hereof;

FIG. 3 is an isometric view of the apparatus in operative connection with a device to be manipulated in accordance herewith;

FIG. 4 is an isometric view like that of FIG. 3 shown in use;

FIG. 5, which includes sub-part FIGS. 5A, 5B, and 5C, presents elevational views of an apparatus hereof in use;

FIG. 6 is an isometric view of an implementation of an apparatus according to the disclosure hereof;

FIG. 7 is a front view of an apparatus like that shown in FIG. 6, illustrating one set of mounting points and one hinge;

FIG. 8 is a right-side view of an apparatus like that shown in FIG. 6, illustrating another set of mounting points and another hinge;

FIG. 9 is a top view of an apparatus like that shown in FIG. 6;

FIG. 10 is a top view of the apparatus like that shown in FIG. 6, illustrating the range of motion of the two hinged portions of the apparatus.

### DETAILED DESCRIPTION

The present invention is directed generally to a dual hinge bracket that allows communications and or data equipment components to swing outward from mounting points within a standard size communication rack assembly to provide rear access to the components for communications and power wiring, inter alia. The dual hinge bracket may have counter swinging hinges that allow the component to move horizontally within a standard sized enclosure and swing outward and away from the enclosure.

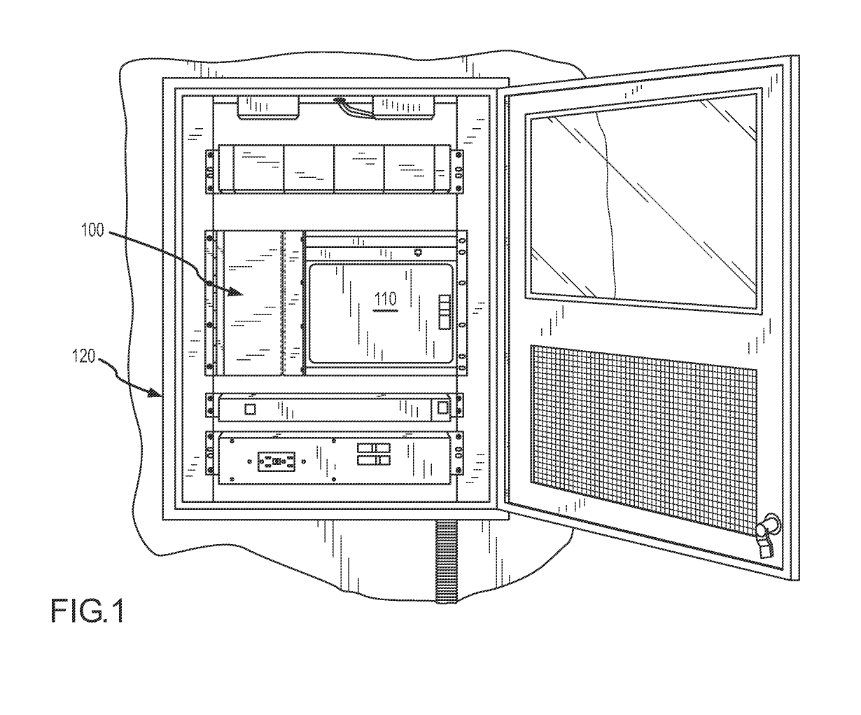

Accordingly, such an apparatus 100, also referred to in some instances, as a device 100, is illustrated, for example in FIG. 1, and may advantageously be used to mount a telecommunications device 110 within a standard size communication rack assembly 120 to provide rear access to the components for communications and power wiring.

The apparatus 100 may be particularly adapted for use with a particular telecommunications device 110 such as the Cisco Systems, Inc. ONS 15310-MA as described herein. As such the apparatus 100 may provide for rear access to the rear of such a device 120 as well as to others or the remainder of the components within a communication rack assembly 120. Such a configuration may provide for improved and moveable mounting of the telecommunications device 110 and advantageous accessibility within the remainder of the telecommunication rack assembly. Accessories and/or alternatives can be provided for use with the apparatus for directing and/or enhancing the nature and direction of the outward movement of the telecommunications device 110. A system for equipment mounting and a method for use of the apparatus are also described.

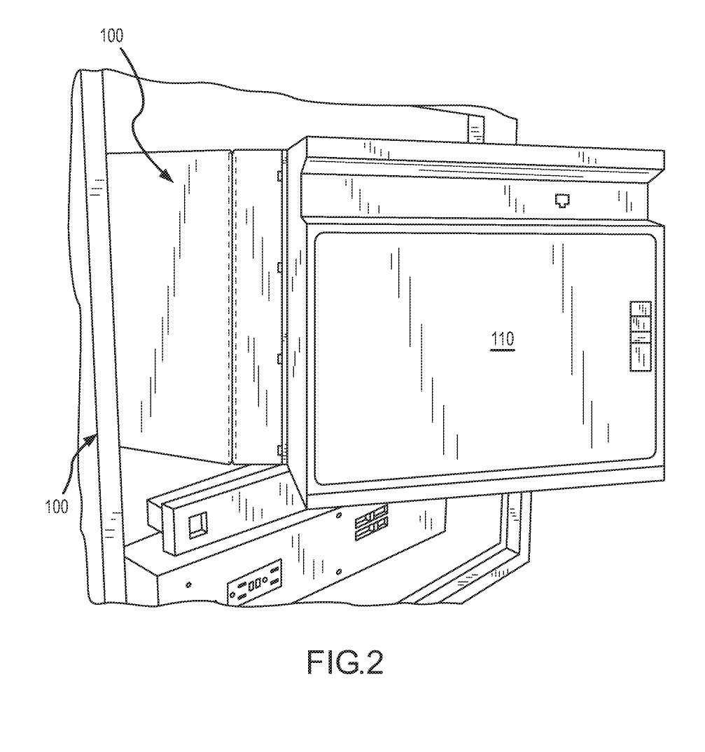

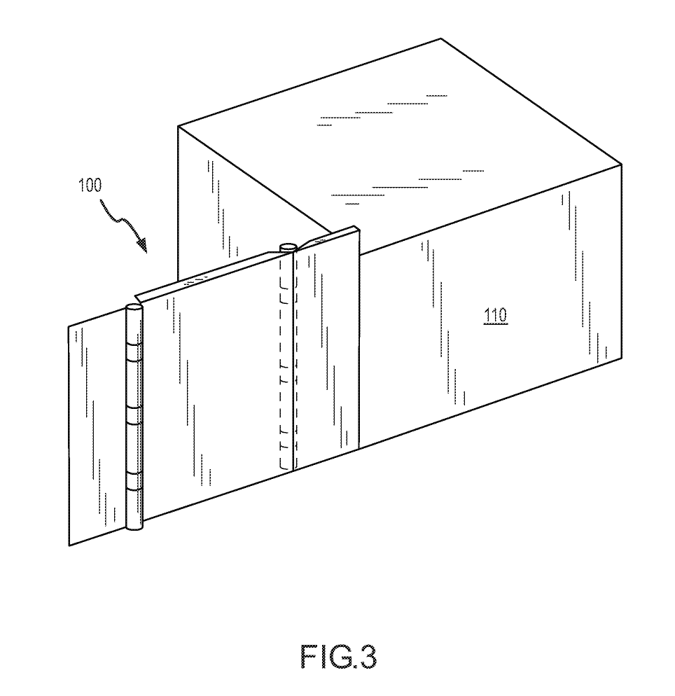

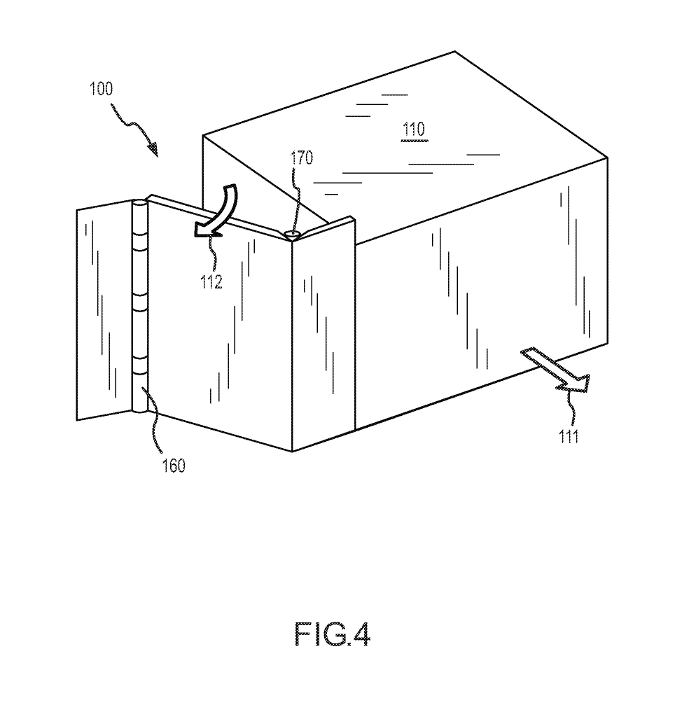

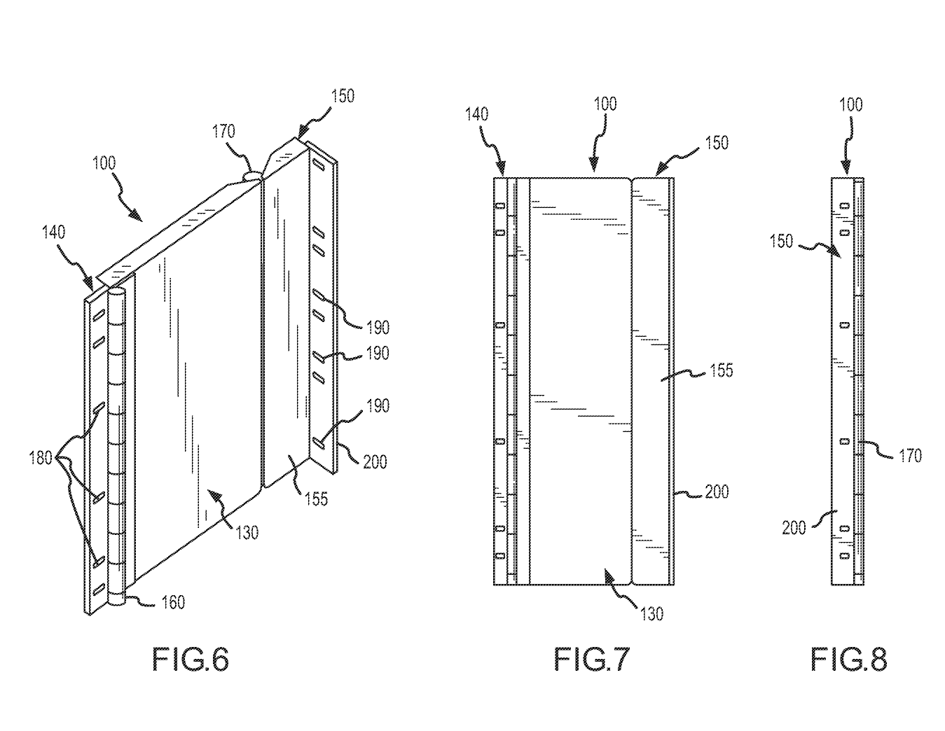

FIG. 2 shows a movement of a device 110 out from an enclosure 120 through use of an apparatus 100 hereof. In the more schematic views of FIGS. 3 and 4, which show the apparatus 100 and the device 100 apart from an enclosure 120, one may see in FIG. 3 the substantially flat, mounted position of a device 110 as it would be when disposed within the enclosure (not shown in FIG. 3). Then, in moving to the position of FIG. 4, the device 110 is shown as it might be moved outwardly, see arrow 111. During this motion the apparatus 100 will be subjected to a rotational movement, see arrow 112, which may be achieved through the arrangement of component parts including the two hinges, 160 and 170, described in further detail relative to FIGS. 6-10, below.

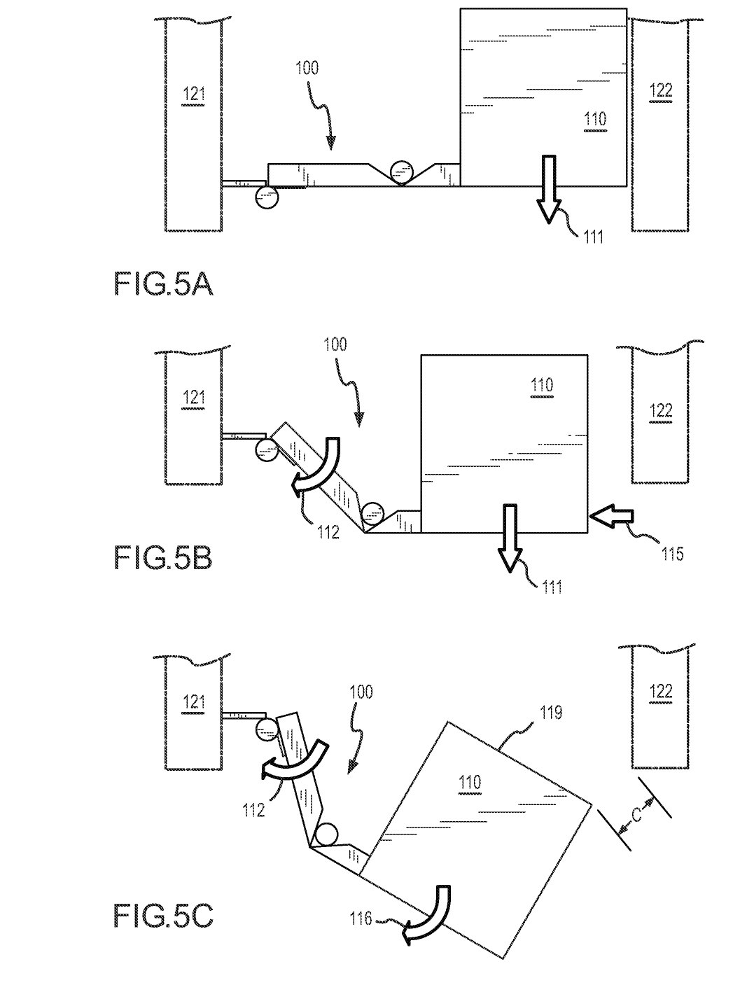

FIG. 5 provides a top plan view of this action of apparatus 100 in movement of the device 100 relative to the respective sidewalls 121 and 122 of enclosure 120. More particularly, in FIG. 5A, the device 110 is shown disposed within the enclosure 120 between side walls 121 and 122. Movement is then initiated outwardly, see arrow 111. Then in relation to the position of FIG. 5B, some separation is achieved from sidewall 122 as shown by arrow 115. Then a still further movement to the exemplar position of FIG. 5C may achieve a clearance C between the device 110 and the sidewall 122 so that the device 110 may be substantially fully removed from within the enclosure 120. Further rotation, see arrow 112, and new arrow 116, may then provide for full access to the rear 119 of the device 110.

As shown in more detail in FIGS. 6-10, an apparatus 100 for providing for rear access to the remainder of the components within a communication rack assembly may include several parts, many of which are moving parts: a substantially planar portion 130 disposed between a first end member 140 and a second end member 150. The first end member 140 may be affixed to the planar portion 130 by way of a first hinge 160. The second end member 150 may be affixed to the planar portion 130 by way of a second hinge 170. The first end 140 may be affixed to the communication rack assembly 120 by screws or other fixing implements driven through the holes 180 in the first end member 140. The second end member 150 may be affixed to the communication rack assembly 120 by screws or other fixing implements driven through the holes 190 in the second end member 150.

In its resting and undeployed state, the apparatus 100 may be substantially planar, as shown in FIG. 6 as well as in FIGS. 1, 3, and 5A, including the substantially planar portion of the second end 155, see FIGS. 6 and 7, with the exception of the perpendicular portion 200 of the second end. The perpendicular portion 200 of the second end may extend out of the plane of the apparatus 100, as shown. The holes 190 are in and through the perpendicular portion 200 of the second end of the apparatus 100. The holes 190 in the perpendicular portion 200 of the second end member 150 may then be used to mount the telecommunications device 110 to the apparatus 100.

As shown in FIGS. 2, 6, and 7 herein, a front view of the apparatus 100 illustrates how the hinge 160 at the first end member 150 is disposed on the front of the apparatus 100. In its undeployed and resting state, the apparatus 100 may be affixed to the telecommunications rack assembly 120 by screws or other fixing means through the holes 180. The apparatus 100 may then, in its undeployed and substantially planar state, extend perpendicularly from a rail or other mounting portion of the telecommunications rack assembly 120 into the center of the assembly 120, see, e.g., FIG. 1.

Another view as shown in FIG. 8, shows the right side 150 of the apparatus 100. The view herein is of the perpendicular portion 200 of the second end 150, the mounting holes 190, and the hinge 170. This view illustrates that the hinge 170 is disposed on the rear of the apparatus 100, and is otherwise substantially hidden from the front views; but see the top portion visible in FIG. 6.

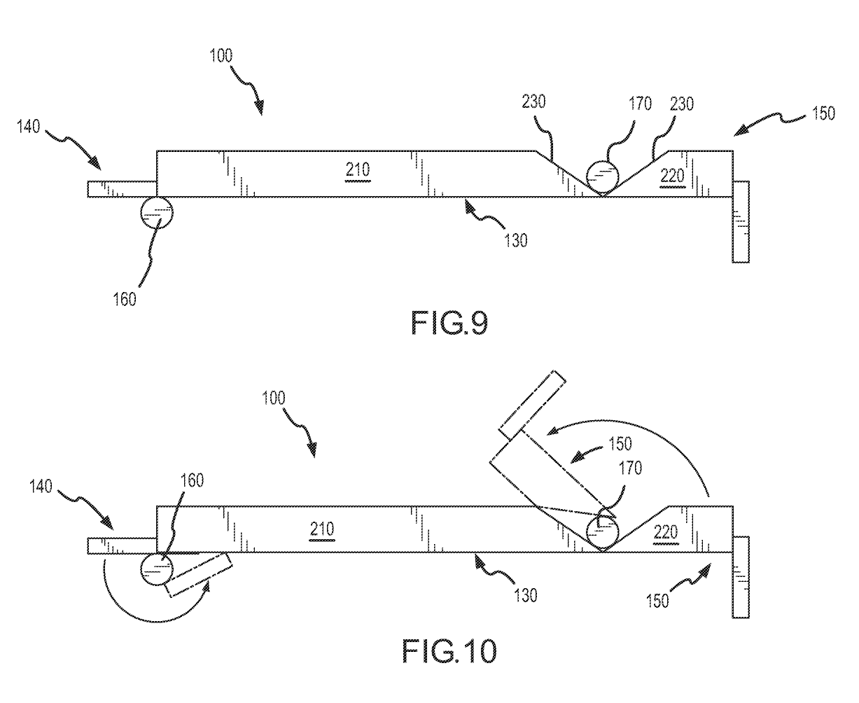

In another view as shown in FIG. 9 herein, a top view of the apparatus illustrates the positioning of the hinges 160 and 170 on opposite sides of the apparatus 100. This view also illustrates the substantial planarity of the apparatus 100 from a top perspective when in a non-deployed state. Also illustrated herein is a view of an overhanging lip 210 of the substantially planar portion 130 and an overhanging lip 220 of the substantially planar portion 155 of the second end 150. This lip may occur on both the top and the bottom of the apparatus 100 on both the substantially planar portion 130 and the substantially planar portion 155 of the second end 150. Further illustrated is what may be asymmetrical cutaway 230 in the lip 210 and the lip 220, allowing for freedom of range of motion of the second end member 150 relative to the main member 130 when rotated on the hinge 170.

FIG. 10 illustrates the range of motion of the hinges. The hinge 160 on the first end may allow rotation of the main member 130 to rotate from an angle of about 0 degrees, relative to the first end member 140, through and beyond an angle of about 180 degrees relative to the first end member 140. The hinge 170 on the second end may allow the second end member 150 to rotate from an angle of about 0 degrees relative to the main member 130, through an angle of about 160 degrees relative to the main member 130.

In some implementations this apparatus may allow the enclosure to use front access support components (power and communications terminations on the front of the equipment versus the rear), which are less expensive than rear access support components. The device would give consumers an opportunity to elect a less expensive and generally smaller front access support unit in lieu of a more expensive and generally larger rear access unit. The front access support components may also promote convenience of access and ability to repair the internal mechanisms that may be mounted on the device.

Incorporation of the device into an enclosure may result in a fewer number of overall moving parts or pieces within the overall enclosure. Other solutions may require several moving pieces or other enabling pieces to allow the communications componentry to move in such a manner as to allow rear access. For example, such a multi-piece solution might require: a separate mount for the equipment; a receiving piece to attach the mounted equipment to the overall structure, a way to attach or detach the equipment from the overall structure; a latch; and other possible moving pieces. The present device may achieve such a result with a single, hinged moving piece.

The device may provide for a smaller overall enclosure that reduces the overall volume of the enclosure or the communications system. Generally speaking, the greater the depth of enclosure of a communications system, particularly one that is wall-mounted, the more difficult the access to the parts that may be in the rear of the enclosure. Inclusion of the device within an enclosure may provide for a more compact overall arrangement of the communications components. Accordingly, incorporation of the device into an enclosure may increase the efficiency of use of space within the enclosure.

The manufacture of the device may be advantageous relative to the manufacture of other access solutions for telecommunications systems. The manufacture of the device may be straightforward and uses basic materials that are readily available. The cost of manufacture of the device may be less costly than comparable methods of manufacture of other access solutions for telecommunications systems.

The device may also be visually more appealing than previously proposed solutions. The device may be manufactured in a manner that results in a sleek, efficient, industrial appearance. Whereas previously, devices manufactured for the mounting of telecommunications components have had a bulky and unfinished appearance, the finishes that may be used on the device are aesthetically appealing, and the design elements are minimalist and streamlined.

The manufacture of the device may be achieved through use of commercially available heavy-duty piano hinges and cold rolled steel plating. In one embodiment, the cold rolled steel plating may be of the 11-gauge variety. The cold rolled steel and the heavy-duty piano hinge may be electrically spot welded to the steel plate. The apparatus may be then be finished with a clear anodized coating, or may remain unfinished. The clear anodized coating may give the apparatus a clean and finished appearance, and may also protect the apparatus from degradation and ordinary wear and tear.

The device may be manufactured by securing the hinges to the mounting plates in opposing directions. Thereby, the apparatus, when mounted in the overall system, may swing laterally and outward. The device may be designed to accommodate the weight and dimensions of a desired component or electrical wiring, which may thereby be mounted to the device in a structurally sound manner. The device may then swing laterally and outward while bearing the weight of the component or electrical wiring.

The device may be specially adapted to secure a Cisco Systems, Inc. ONS 15310-MA Optical Multiplexer in a 19″ telecom rack assembly. The Cisco ONS 15310-MA weighs between about 21 and about 34 lbs depending on how it is equipped. The device may be designed to support approximately 40 to approximately 50 lbs when using cold-rolled steel.

For such a weight, and when using cold rolled steel, the thickness of the device may be a uniform thickness of about one-half of one inch (0.5″) to about twenty-three hundredths of an inch (0.1″). The thickness may depend on the commercially available steel used in the manufacture of the apparatus.

The shape and/or dimensions of some particular embodiments may include: about 10.375 inches in length (parallel to the hinges); about 7.5 inches in width (perpendicular to the hinges). A first plane of the L-shaped portion of the apparatus may be 1.5313 inches in width, and a second plane of the L-shaped portion of the apparatus may be about 0.09063 inches in width. The radius of the holes at the first end of the apparatus may be about 0.1297 inches, and the radius of the holes at the second end of the apparatus may be about 0.1094 inches. The range of motion of the hinge at the first end of the apparatus may be between about 0 degrees and up to 180 degrees, and the range of motion of the hinge at the second end of the apparatus may be between about 0 degrees and up to about 160 degrees.

The hole alignment on both the first and the second ends of the apparatus may be configured to adapt to the mounting holes on the Cisco ONS 15310-MA. The hole alignment on both the first and the second ends of the apparatus may also be configured to adapt to mounting holes in other manufacturers' systems.

The device may be advantageous over current solutions in that it has been designed and manufactured in such a way as to reduce or otherwise be adapted to overall cabinet size, reduce cost of manufacture of the apparatus and of the overall system, and make the overall system easier to install, access, and maintain. This created an overall system that may simplify accessibility to a component of the machine that requires rear access.

An apparatus and the inventive methods for making and/or using such an apparatus have been described above in considerable detail. This was done for illustrative purposes. Neither the specific implementations of the invention as a whole, nor those of its features, limit the general principles underlying the invention. In particular, the invention is not necessarily limited to the specific constituent materials and proportions of constituent materials used in making the compositions. The invention is also not necessarily limited to an apparatus as specifically described herein, but may extend to other applications as well. The specific features described herein may be used in some implementations, but not in others, without departure from the spirit and scope of the invention as set forth. Many additional modifications are intended in the foregoing disclosure, and it will be appreciated by those of ordinary skill in the art that, in some instances, some features of the invention will be employed in the absence of other features. Additional features may be implemented as well. The illustrative examples therefore do not define the metes and bounds of the invention and the legal protection afforded the invention, which function is served by the claims and their equivalents.

Accordingly, what is claimed is:

1. A dually hinged apparatus for mounting an equipment component in a moveable disposition within a housing, the dually hinged apparatus comprising:
a substantially planar portion having a first end and a second end;
a first hinge operatively connected to the planar portion near the first end of the planar portion;
a first end member operatively coupled to the substantially planar portion via the first hinge near the first end of the planar portion;
a second hinge operatively connected to the planar portion near the second end of the planar portion;
a second end member coupled to the substantially planar portion via the hinge near the second end of the planar portion;
wherein the first end member is adapted to be connected to a housing;
wherein the second end member is adapted to be connected to an equipment component; and,
wherein the apparatus is adapted for mounting the equipment component within the housing in a movable disposition.

2. An apparatus as recited in claim 1, wherein the first end member near the first end of the planar portion contains one or more mounting holes for mounting the apparatus to the housing.

3. An apparatus as recited in claim 1, wherein the second end member near the second end of the planar portion contains one or more mounting holes for mounting the apparatus to the equipment component.

4. An apparatus as recited in claim 2, wherein the first end member near the first end of the planar portion is adapted to be coupled to a telecommunications rack assembly.

5. An apparatus as recited in claim 4 wherein the telecommunications rack assembly is of substantially standard size.

6. An apparatus as recited in claim 3, wherein the second end member near the second end of the planar portion is adapted to be coupled to one or more of telecommunications device, a networking device, an Ethernet device, an optical communications device and a multi-service device for moveable mounting in a housing.

7. An apparatus as recited in claim 6 wherein the housing is a telecommunications rack assembly.

8. An apparatus as recited in claim 1, wherein the planar portion has a front face and a rear surface opposite the front face, and wherein the first hinge near the first end of the planar portion is mounted on the front face of the planar portion in opposition to the second hinge near the second end of the planar portion, the second hinge being is mounted on the rear surface of the planar portion.

9. An apparatus as recited in claim 1, wherein the second end member is substantially L-shaped, the L-shape being defined by first and second planes being substantially perpendicular to each other, and the second end member is oriented in such a manner that the first plane of the second end member is substantially coplanar with the substantially planar portion when the apparatus is in a non-deployed disposition, and the second plane of the second end member is at a right angle to the first plane of the second end member and pointing away from the second hinge which couples the second end member to the substantially planar portion.

10. An apparatus as recited in claim 1, wherein the apparatus is adapted to provide for access to the rear of an equipment component to be connected thereto.

11. An apparatus as recited in claim 1, wherein the apparatus is adapted to provide for access to one or both of the front and rear of an equipment component to be connected thereto.

12. An apparatus as recited in claim 1, wherein the apparatus is adapted to provide for access to one or both of the front and rear of an equipment component, a and provide for access to one or more electronic wiring mounts on either the front or rear side of the equipment component.

13. A system for equipment mounting, the system comprising:
a housing for one or more equipment components;
an equipment component adapted to be mounted within the housing;
a substantially planar, dually hinged apparatus for mounting the equipment component in the housing, the apparatus including:
a substantially planar portion having a first end and a second end;
a first hinge operatively connected to the planar portion near the first end of the planar portion;
a first mounting member operatively connected to the first hinge;
a first series of holes defined in the first mounting member, whereby the first series of holes are adapted to be used to mount the apparatus to the housing;
a second hinge operatively connected to the planar portion near the second end of the planar portion;
a second mounting member operatively connected to the second hinge;
a second series of holes at the second end of the planar portion, whereby the second series of holes are adapted to be used to mount the apparatus to the housing;
wherein the equipment component is mounted within the housing in a movable disposition to provide access to the rear of the equipment component.

14. A system as recited in claim 13, wherein the system is adapted to provide for access to one or both of the front and rear of an equipment component to be connected thereto.

15. A system as recited in claim 13, wherein the apparatus is adapted to provide for access to one or both of the front and rear of an equipment component, a and provide for access to one or more electronic wiring mounts on either side of the substantially planar apparatus.

16. A system as recited in claim 13, wherein the housing is a substantially standard size telecommunications rack assembly.

17. A system as recited in claim 13, wherein the equipment component is one or more of a telecommunications device, a networking device, an Ethernet device, an optical communications device and a multiservice device for moveable mounting in a housing.

18. A method for mounting equipment within a larger assembly, the method comprising:
providing a substantially planar, dually hinged and moveable apparatus for mounting equipment;
coupling such apparatus to a larger assembly in a moveable disposition relative to the larger assembly; and
mounting one or more pieces of equipment onto said apparatus.

19. A method for mounting equipment according to claim 18 which further provides for:
accessing the rear side of the one or more pieces of equipment through:
moving the moveable apparatus including rotating the dual hinges thereof.

20. A method according to claim 19 wherein the one or more pieces of equipment mounted on said apparatus are adapted by said apparatus to alternately be disposed within the housing or outside the housing while remaining mounted to said apparatus.
